(19) United States
(12) Patent Application Publication
(10) Pub. No.: US 2003/0157768 A1
(43) Pub. Date: Aug. 21, 2003

(54) Method of manufacturing semiconductor integrated circuit device

(75) Inventors: Shinichi Nakabayashi, Hitachinaka (JP); Hidekazu Okuda, Takasaki (JP); Kosaku Tachikawa, Hitachinaka (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 10/365,421

(22) Filed: Feb. 13, 2003

(30) Foreign Application Priority Data
Feb. 19, 2002 (JP) 2002-042193

(51) Int. Cl. H01L 21/336; H01L 21/4763

(52) U.S. Cl. 438/258; 438/633

(57) ABSTRACT

Disclosed is a method to achieve the planarization of a BPSG film and reduction of micro-scratches on a BPSG film by the CMP method. A BPSG film is deposited over a main surface of a substrate on which MISFETs have been formed, and then, a surface of the BPSG film is planarized by the CMP method. Thereafter, a thermal treatment is performed to the substrate to reflow the BPSG film, thereby removing the micro-scratches on the surface of the BPSG film caused by the polishing. At this time, the amount of polishing of the surface of the BPSG film is controlled within a range of 90 to 300 nm, preferably 100 to 250 nm, and more preferably 120 to 200 nm.

### TECHNICAL FIELD OF THE INVENTION

The present invention relates to a technique for manufacturing a semiconductor integrated circuit device. More particularly, the present invention relates to a technique effectively applied to the manufacture of a semiconductor integrated circuit device, comprising the step of planarizing a BPSG (Boro Phospho Silicate Glass) film by the use of the CMP (Chemical Mechanical Polishing) method.

### BACKGROUND OF THE INVENTION

Conventionally, the reflow method of a BPSG film and the CMP method are known as the planarization technique of an interlayer dielectric in the process of forming a multilayer wiring in a semiconductor integrated circuit (LSI).

The reflow method of a BPSG film is a technique that a thermal treatment at a high temperature of about 900° C. is performed to an insulating film made of silicon oxide in which B (boron) and P (phosphorus) are added to enhance the fluidity, thereby reflowing the surface thereof. Also, the CMP method is a technique for polishing the surface of a wafer while supplying polishing slurry to a platen on which a polishing pad made of hard resin is attached. Generally, the one obtained by dispersing polishing particles such as silica (silicon oxide) into purified water and adding alkali for adjusting pH is used as the polishing slurry. However, with respect to the CMP method in which the wafer is polished by the use of the polishing slurry containing silica, the problem is pointed out, that is, the micro-scratches are caused on the surface of a wafer due to coarse flocculated silica particles in the slurry, and thus, the manufacturing yield and the reliability of the LSI are deteriorated.

Japanese Patent Application Laid-Open Nos. 2000-164713 (Yamazaki) and 10-150035 (Tsunoda et al.) disclose the planarization technique of an insulating film using both the reflow method of a BPSG film and the CMP method.

According to an aspect of the planarization technique disclosed in the first gazette (2000-164713), a first wiring layer is formed on a first interlayer dielectric, and then, a BPSG film with a thickness of about 800 nm is deposited thereon by the CVD method. Thereafter, a thermal treatment is performed in a nitrogen atmosphere at 850° C., thereby forming a second interlayer dielectric. Next, about 400 nm of the second interlayer dielectric composed of the BPSG film is polished by the CMP method, thereby planarizing the surface thereof. Thereafter, a thermal treatment in a nitrogen atmosphere (or oxygen atmosphere) at 850 to 900° C. is performed to reflow the BPSG film, thereby removing micro-scratches on the surface of the BPSG film caused by the above-described polishing.

Also, according to an aspect of the planarization technique disclosed in the second gazette (10-150035), a BPSG film with a thickness of 13500 Å is deposited as an insulating film provided below the first layer metal wiring, and then, the surface thereof is planarized by the use of the CMP method. Thereafter, a thermal treatment at 900° C. for about 4 to 5 minutes is performed in a nitrogen atmosphere to reflow the BPSG film, thereby removing the micro-scratches on the BPSG film caused by the above-described polishing.

### SUMMARY OF THE INVENTION

In the manufacture of a memory-logic embedded LSI in which a flash memory and a logic LSI are formed on the same semiconductor substrate, the inventors of the present invention have examined a process in which a BPSG film is used to constitute an insulating film between a MISFET (Metal Insulator Semiconductor Field Effect Transistor) and a first layer metal wiring provided thereon.

In this case, since a gate electrode of the MISFET that constitutes a flash memory has a laminated structure in which a control gate electrode is formed on a floating gate electrode, the gate electrode has a height larger than that of a gate electrode of a normal MISFET. Therefore, when a BPSG film is deposited on the semiconductor substrate on which the MISFET that constitutes a flash memory has been formed, large irregularities are caused on the surface thereof.

As a result, in the case where both the CMP method and the reflow method are used to achieve the planarization of the BPSG film as in the conventional technique described above, when the amount of polishing of the BPSG film is insufficient, the irregularities on the surface are not completely eliminated.

Meanwhile, when a larger amount of the BPSG film is polished, the polishing time is also increased. Therefore, the throughput of the polishing process is decreased and the number of the micro-scratches is increased. In addition, in the case where a larger amount of the BPSG film is polished, since the thickness of the BPSG film is decreased, the distance between the first layer metal wiring provided on the BPSG film and the gate electrode provided below the same is shortened and the parasitic capacitance formed therebetween is increased. As a result, the high-speed operation of the MISFET that constitutes the logic LSI is hindered. Furthermore, the process for performing the thermal treatment to reflow the BPSG film at a high temperature and for a long period is also available as another planarization method of the surface of the BPSG film without increasing the amount of polishing of the BPSG film. However, such a process is not preferable because it causes the fluctuation of the characteristics of the MISFET.

An object of the present invention is to provide a technique capable of achieving the planarization of a BPSG film by the use of the CMP method and achieving the reduction of the micro-scratches formed thereon.

Another object of the present invention is to provide a technique capable of optimizing the amount of polishing of a BPSG film when both the CMP method and the reflow method are used in the planarization of a BPSG film.

The above and other objects and novel characteristics of the present invention will be apparent from the description and the accompanying drawings of this specification.

The typical ones of the inventions disclosed in this application will be briefly described as follows.

In the method of manufacturing a semiconductor integrated circuit device as an aspect of the present invention, a first insulating film mainly made of BPSG is formed on a main surface of a semiconductor substrate. Subsequently, the surface of the first insulating film is polished by the use of the CMP method. Thereafter, a thermal treatment is performed to the semiconductor substrate to reflow the first insulating film. At this time, the amount of polishing of the first insulating film is controlled within a range of 90 to 300 nm, preferably, 100 to 250 nm, and more preferably 120 to 200 nm.

Note that the chemical mechanical polishing (CMP) method in this application generally indicates the polishing method in which a surface to be polished is contacted to a polishing pad made of a sheet material like a relatively soft fabric, and in this state, the polishing pad is relatively moved in a surface direction while supplying the polishing slurry.

The polishing slurry generally indicates liquid colloidal suspension obtained by mixing polishing particles (dispersoid) into water and chemical etchant (dispersion medium). Also, the polishing particles generally indicate fine particles such as silica, ceria, zirconia, and alumina.

The polishing of a BPSG film indicates the polishing performed under the same conditions as those when a BPSG film having a flat surface and deposited on a flat substrate is polished.

In the embodiment described below, the present invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiment described below, when the number of an element (including number of pieces, values, amount, range, or the like) is mentioned, the number of the element is not limited to a specific number unless otherwise stated or except the case where the number is apparently limited to a specific number in principle. The number larger or smaller than the specified number is also applicable.

Similarly, in the embodiment described below, when the shape of the components, the positional relation thereof, and the like are mentioned, the substantially approximate and similar shapes and the like are included therein unless otherwise stated or except the case where it can be understood that they are apparently excluded in principle. This condition is also applicable to the numerical value and the range described above.

Also, when a semiconductor integrated circuit device is mentioned in this application, it is not limited to the one formed on a single crystal silicon substrate and includes the one formed on an SOI (Silicon On Insulator) substrate and on a substrate for a TFT (Thin Film Transistor) liquid crystal device unless otherwise stated.

### BRIEF DESCRIPTIONS OF THE DRAWINGS

FIG. 1 is a sectional view showing the principal part of a semiconductor substrate for explaining the method of manufacturing a memory-logic embedded LSI according to an embodiment of the present invention;

FIG. 2 is a sectional view showing the principal part of the semiconductor substrate for explaining the method of manufacturing a memory-logic embedded LSI according to the embodiment of the present invention;

FIG. 3 is a sectional view showing the principal part of the semiconductor substrate for explaining the method of manufacturing a memory-logic embedded LSI according to the embodiment of the present invention;

FIG. 4 is a sectional view showing the principal part of the semiconductor substrate for explaining the method of manufacturing a memory-logic embedded LSI according to the embodiment of the present invention;

FIG. 5 is a sectional view showing the principal part of the semiconductor substrate for explaining the method of manufacturing a memory-logic embedded LSI according to the embodiment of the present invention;

FIG. 6 is a sectional view showing the principal part of the semiconductor substrate for explaining the method of manufacturing a memory-logic embedded LSI according to the embodiment of the present invention;

FIG. 7 is a sectional view showing the principal part of the semiconductor substrate for explaining the method of manufacturing a memory-logic embedded LSI according to the embodiment of the present invention;

FIG. 8 is a sectional view showing the principal part of the semiconductor substrate for explaining the method of manufacturing a memory-logic embedded LSI according to the embodiment of the present invention;

FIG. 9 is a sectional view showing the principal part of the semiconductor substrate for explaining the method of manufacturing a memory-logic embedded LSI according to the embodiment of the present invention; and

FIG. 10 is a sectional view showing the principal part of the semiconductor substrate for explaining the method of manufacturing a memory-logic embedded LSI according to the embodiment of the present invention.

### DESCRIPTION OF THE PREFERRED EMBODIMENTS

Hereinafter, an embodiment of the present invention will be described in detail with reference to the accompanying drawings. Note that components having the same function are denoted by the same reference symbols throughout the drawings for describing the embodiment, and the repetitive description thereof is omitted.

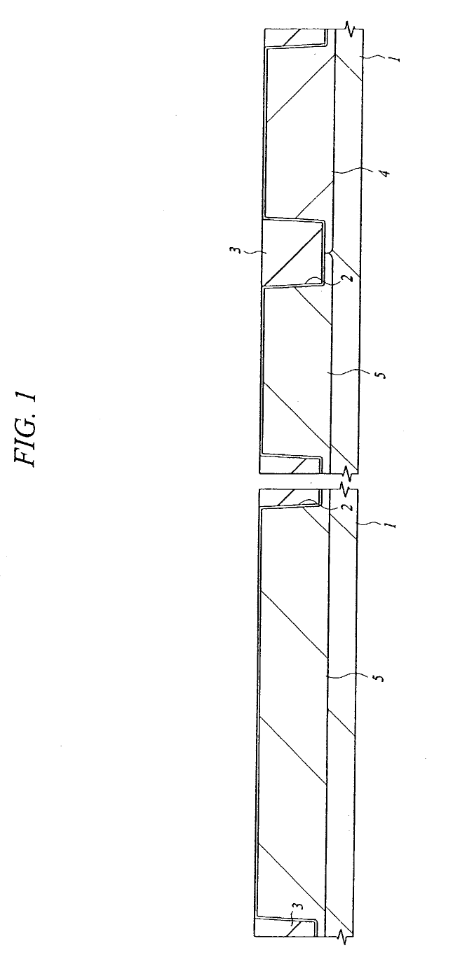

In this embodiment, the present invention is applied to the manufacture of a memory-logic embedded LSI in which a flash memory (non-volatile semiconductor memory device capable of the electrical batch erasing and the electrical rewriting) and a logic LSI are formed over the same semiconductor substrate, and a method of manufacturing the same will be described below with reference to FIGS. 1 to 10. Note that the left side areas in each of FIGS. 1 to 10 are sectional views of a semiconductor substrate showing a part of a flash memory forming region, and the right side areas are sectional views of a semiconductor substrate showing a part of a logic LSI forming region.

First, as shown in FIG. 1, an isolation trench 2, n-type wells 4, and p-type wells 5 are formed over the main surface of a semiconductor substrate 1 (hereinafter, referred to be as a substrate) which is made of single crystal silicon. The isolation trench 2 is formed in the following manner. That is, the main surface of the substrate 1 is etched to form trenches, and then, a silicon oxide film 3 is deposited on the substrate 1 and in the trenches by the CVD method. Thereafter, the silicon oxide film 3 outside the trenches is polished and removed by the CMP method. Also, the n-type well 4 is formed by the ion implantation of B (boron) into a part (forming region of a p-channel MISFET of the logic LSI) of the substrate 1, and the p-type well 5 is formed by the ion implantation of P (phosphorus) into other parts (a forming region of an n-channel MISFET of the logic LSI and a flash memory forming region) of the substrate 1.

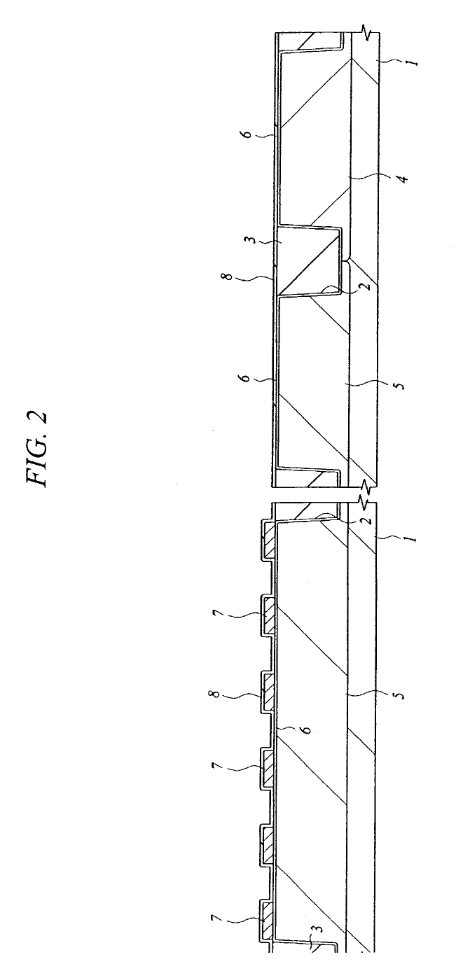

Next, as shown in FIG. 2, the wet oxidation of the substrate 1 is performed to form a gate insulating film 6 comprised of a silicon oxide film with a thickness of about 7 nm over each surface of the n-type well 4 and the p-type well 5. Subsequently, floating gate electrodes 7 of the MISFETs constituting a flash memory are formed on the gate insulating film 6 in a memory region. Thereafter, an ONO film 8 is formed over the substrate 1 and the floating gate electrodes 7.

The floating gate electrode 7 is formed in the following manner. That is, a polycrystalline silicon film with a thickness of about 150 nm is deposited over the substrate 1 by the CVD method, and then, the polycrystalline silicon film is patterned by the use of the photolithography technique and the dry etching technique. Also, the ONO film 8 is used as second gate insulating films of the MISFETs constituting a flash memory and is formed by sequentially depositing a silicon oxide film with a thickness of 5 nm, a silicon nitride film with a thickness of 7 nm, and a silicon oxide film with a thickness of 4 nm over the substrate 1 by the CVD method.

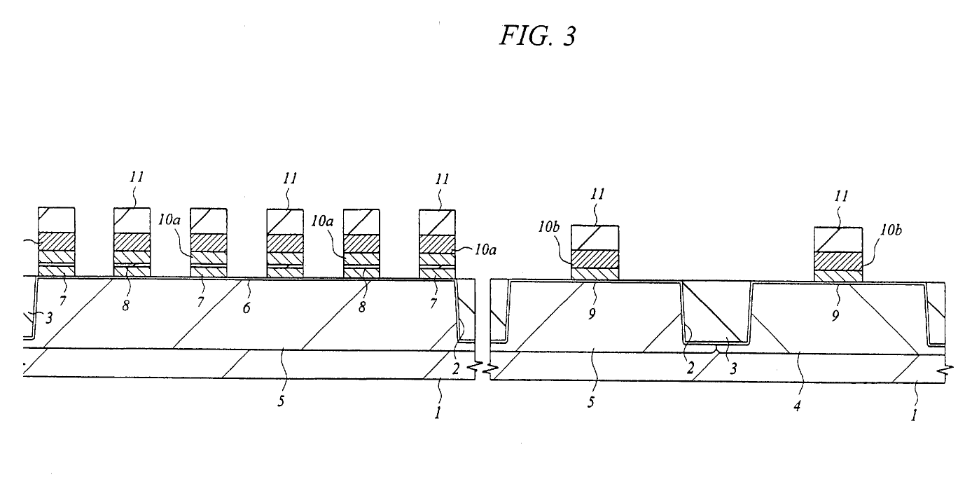

Next, as shown in FIG. 3, the gate insulating film 6 and the ONO film 8 in the logic LSI forming region are removed, and a gate insulating film 9 comprised of a silicon oxide film is newly formed. Thereafter, control gate electrodes 10a of the MISFETs constituting a flash memory and gate electrodes 10b of the MISFETs constituting a logic LSI are both formed.

The control gate electrode 10a and the gate electrode 10b are formed in the following manner. That is, a polycrystalline silicon film with a thickness of about 80 nm is deposited over the substrate 1 by the CVD method. Subsequently, a W (tungsten) silicide film with a thickness of about 100 nm is deposited by the sputtering method, and then, a silicon nitride film 11 with a thickness of about 150 nm is deposited by the CVD method. Thereafter, these films are patterned, by the use of the photolithography technique and the dry etching technique.

The control gate electrode 10a (and the floating gate electrode 7) of the MISFET constituting a flash memory is designed to have a gate length of about 0.45 μm and the gate electrode 10b of the MISFET constituting a logic LSI is designed to have a gate length larger than 0.45 μm. Also, the space between the adjacent control gate electrodes 10a (and the floating gate electrodes 7) is set to about 0.8 μm and the space between the adjacent gate electrodes 10b is set larger than 0.8 μm.

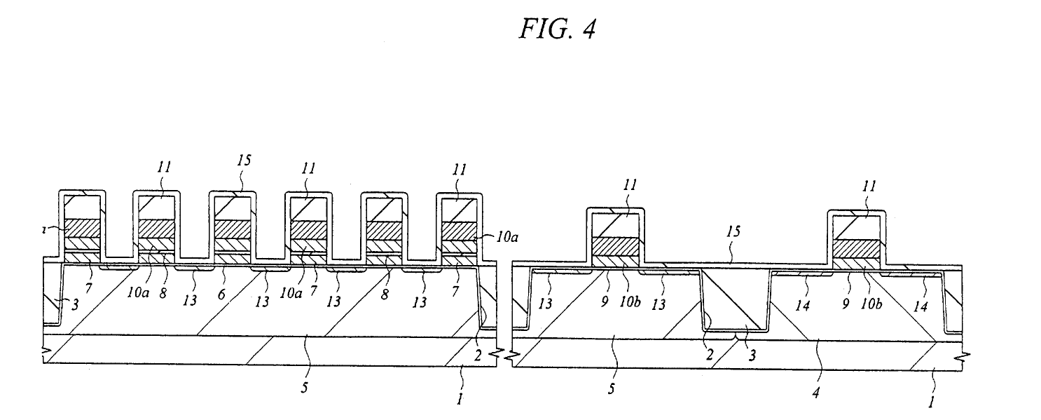

Next, as shown in FIG. 4, P (phosphorus) or As (arsenic) is ion-implanted into the surface of the p-type well 5 to form n⁻-type semiconductor regions 13, and B (boron) is ion-implanted into the surface of the n-type well 4 to form p⁻-type semiconductor regions 14. Thereafter, a silicon nitride film (or a laminated film of a silicon oxide film and a silicon nitride film) 15 with a thickness of about 30 nm is deposited over the substrate 1 by the CVD method.

The n⁻-type semiconductor region 13 and the p⁻-type semiconductor region 14 are formed in order to allow each of the MISFETs constituting the flash memory and the MISFETs constituting the logic LSI to have the LDD (Lightly Doped Drain) structure. In addition, the silicon nitride film 15 is deposited in order to have the later-described contact holes formed by a self alignment manner in the small spaces between the control gate electrodes 10a (and the floating gate electrodes 7).

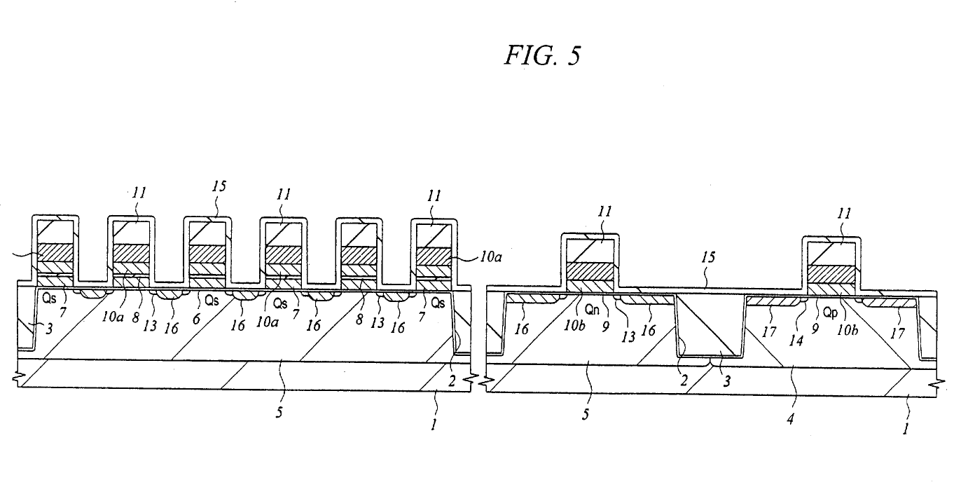

Next, as shown in FIG. 5, P (phosphorus) or As (arsenic) is ion-implanted into the surface of the p-type well 5 to form n⁺-type semiconductor regions (source and drain) 16, and B (boron) is ion-implanted into the surface of the n-type well 4 to form p⁺-type semiconductor regions (source and drain) 17. In the process so far, the n-channel MISFETs Qs constituting a flash memory and the n-channel MISFET Qn and the p-channel MISFET Qp constituting a logic LSI are completed.

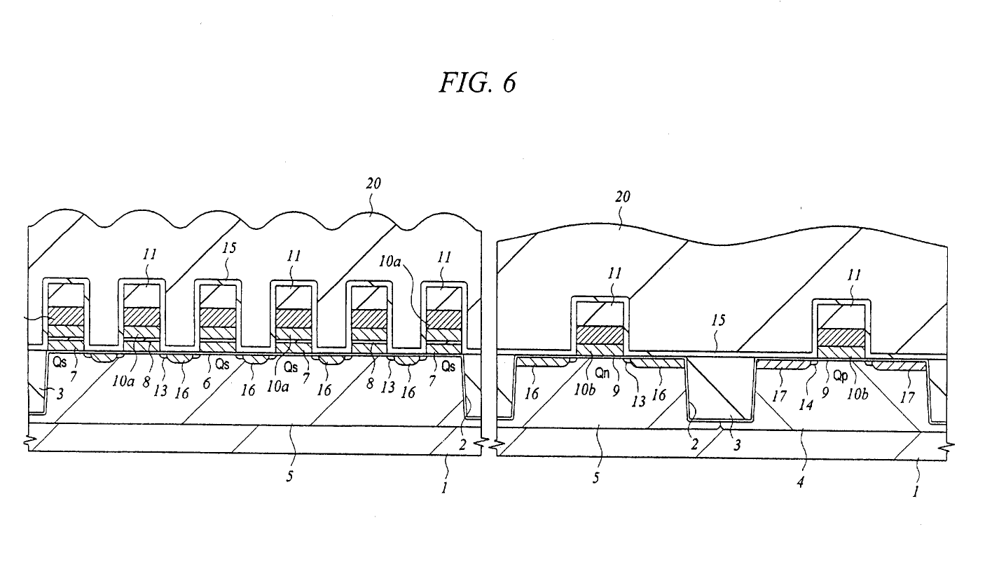

Next, as shown in FIG. 6, a BPSG film 20 is deposited over the substrate 1. The BPSG film 20 is deposited by the thermal CVD method at the deposition temperature of 500° C. by the use of the source gas containing main components of tetraethoxy silane and ozone and added with triethyl borate and triethyl phosphate.

The thickness of the BPSG film 20 over the flat portion of the substrate 1 (over the portion where the MISFET is not formed) is set to about 1 μm. Also, the concentration of B (boron) contained in the BPSG film 20 is, for example, 13 molar concentration, and that of P (phosphorus) is 6 molar concentration. Note that it is also possible to deposit a silicon oxide film containing no impurities such as B (boron) and P (phosphorus) with a thickness of about 100 nm in advance of the deposition of the BPSG film 20, and then, deposit the BPSG film 20 on the silicon oxide film. This silicon oxide film functions to prevent the fluctuation of the characteristics of the MISFET by preventing the diffusion of B (boron) and P (phosphorus) contained in the BPSG film 20 into the gate electrodes 10a and 10b and into the substrate 1 in the later thermal treatment.

Next, a thermal treatment for about 20 minutes at 850° C. is performed in a nitrogen gas atmosphere. By this thermal treatment, B (boron) and P (phosphorus) are evenly diffused in the BPSG film 20. Therefore, the film quality of the BPSG film 20 is improved. Note that, at this time, it is possible to improve a reflow property of the BPSG film 20 by performing the thermal treatment in a nitrogen gas atmosphere containing oxygen gas of about 1 wt %.

As shown in FIG. 6, when the BPSG film 20 is deposited over the substrate 1 over which the MISFETs (Qs, Qn, and Qp) have been formed, the irregularities reflecting the heights of the gate electrodes of the MISFETs (Qs, Qn, and Qp) occur on the surface of the film. In particular, since the gate electrode of the n-channel MISFET Qs constituting a flash memory has a laminated structure in which the control gate electrode 10a is formed over the floating gate electrode 7, the gate electrode of the n-channel MISFET Qs is higher than the gate electrode 10b of the MISFETs (Qn and Qp) constituting a logic LSI. Therefore, the BPSG film 20 in the flash memory forming region has larger surface irregularities than those of the BPSG film 20 in the logic LSI forming region.

The irregularities on the surface of the BPSG film 20 causes the reduction in workability of the formation of the wiring to be formed on the BPSG film 20 in the later process. Therefore, in this embodiment, the method as follows is employed for the surface planarization of the BPSG film 20.

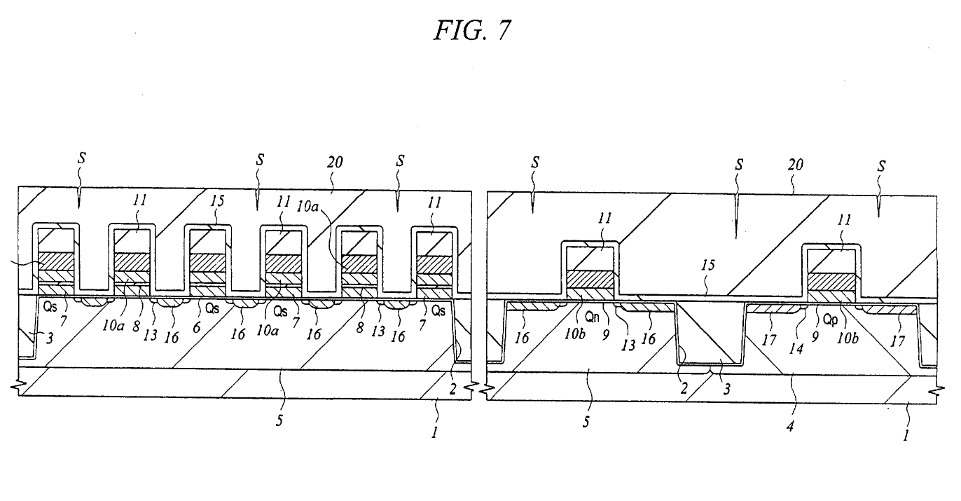

First, as shown in FIG. 7, the surface of the BPSG film 20 is polished by the use of the CMP method. The amount of polishing of the BPSG film 20 is in a range of 90 to 300 nm, preferably 100 to 250 nm, and more preferably 120 to 200 nm. In this embodiment, the amount of polishing of the BPSG film 20 is set to about 150 nm, and the height from the surface of the substrate 1 to the surface of the BPSG film 20 is set to about 1 μm. The surface of the BPSG film 20 is almost planarized by this polishing.

Note that when it is mentioned that the amount of polishing of the BPSG film 20 is set to P nm, it means that the polishing is performed under the same conditions as those of the case where P nm of a BPSG film 20 having a flat surface deposited over a flat substrate is polished. In the case of the BPSG film 20 deposited over the actual substrate 1, the irregularities reflecting the heights of the MISFETs (Qs, Qn, and Qp) in the base layer exist on the surface of the BPSG film 20. Therefore, the amount of polishing thereof differs depending on the positions to be polished.

In general, if the amount of polishing of the BPSG film 20 is increased, the time required for the polishing is also increased. Therefore, the throughput of the polishing process is deteriorated, and also, the number of the micro-scratches is increased. In particular, in the case where the amount of polishing is increased more than 300 nm, the thickness of the BPSG film 20 becomes small. Therefore, the distance between the wiring formed over the BPSG film 20 in the latter process and the gate electrode provided below the film 20 is shortened, and the parasitic capacitance formed therebetween is increased. As a result, the high-speed operation of the MISFET (particularly, MISFET that constitutes a logic LSI) is hindered. Meanwhile, in the case where the amount of polishing of the BPSG film 20 is 90 nm or smaller, the surface irregularities are not eliminated and left in, in particular, the flash memory forming region. Therefore, the amount of polishing of the BPSG film 20 should be set to at least 90 nm or larger and at most 300 nm or smaller.

When polishing the BPSG film 20, the polishing slurry obtained by dispersing silica particles into water is used. Since hydrophilic silanol groups (Si—OH) exist on the surface of silica, the particles (first particles) are flocculated due to the intergranular hydrogen coupling of the silanol groups and the van der Waals force when the silica particles are dispersed into wafer, and the flocculated particles (second particles) having a larger diameter (diameter of particles) than that of the single particle are formed. Therefore, in the polishing slurry in which silica particles (dispersoid) are dispersed into water (dispersion medium), the flocculated particles constitute the abrasive particles.

The flocculated particles have no problem if the diameter is relatively small. However, there exist coarse flocculated particles having a diameter of 1 μm or larger in the actual polishing slurry. Therefore, when the BPSG film 20 is polished by the CMP method, microscopic scratches called micro-scratches S are formed on the surface thereof as shown in FIG. 7. Some of the micro-scratches S formed in the surface of the BPSG film 20 reach the substrate 1 and cause the damages on the surface of the substrate 1. Also, when the micro-scratches S reach the gate electrode, the micro-scratches cause the short-circuit between the wiring formed over the BPSG film 20 and the gate electrode.

For its solution, a thermal treatment is performed to the substrate 1 to reflow the BPSG film 20. The reflow conditions are, for example, 900° C. and about 20 minutes. In this case, it is possible to improve a reflow property of the BPSG film 20 by performing a thermal treatment in a nitrogen gas atmosphere containing oxygen gas of about 1 wt %.

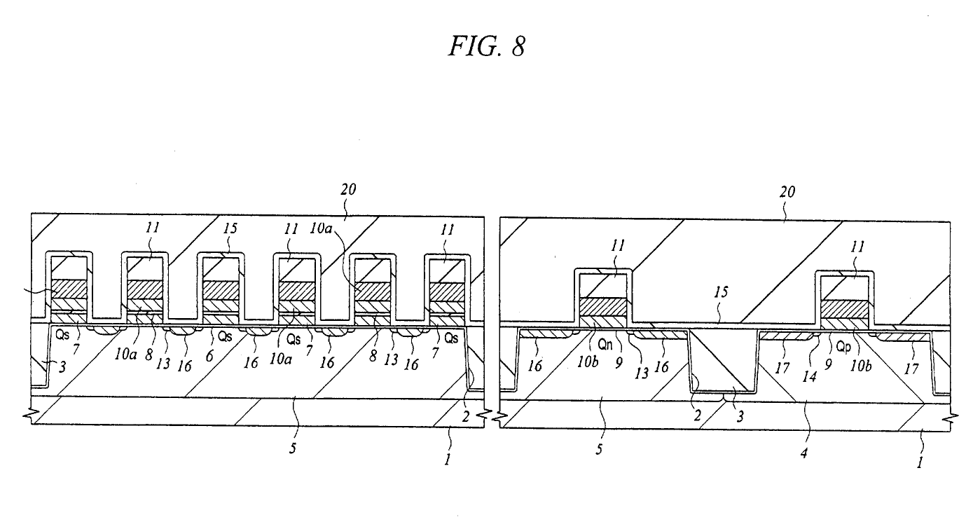

As shown in FIG. 8, by the polishing and the thermal treatment as described above, the planarization of the surface of the BPSG film 20 is almost completed, and almost all of the micro-scratches S are eliminated. Note that the amount of the polishing of the BPSG film 20 and the conditions of the subsequent thermal treatment can be appropriately adjusted depending on the kind of the device. For example, in the case where the design rule of the device is minute, the thermal history in the process must be kept low in order to prevent the fluctuation of the characteristics of a MISFET. Therefore, the BPSG film is planarized under the conditions that the amount of the polishing of the BPSG film 20 is relatively increased, and the subsequent thermal treatment is performed at a relatively low temperature and in a relatively short time. Meanwhile, in the case of the device having a relatively large design rule, the BPSG film is planarized under the conditions that the amount of polishing of the BPSG film 20 is reduced and the subsequent thermal treatment is performed at a relatively high temperature and for a relatively long time. However, in both cases, the amount of polishing of the BPSG film 20 should be within the range as described above.

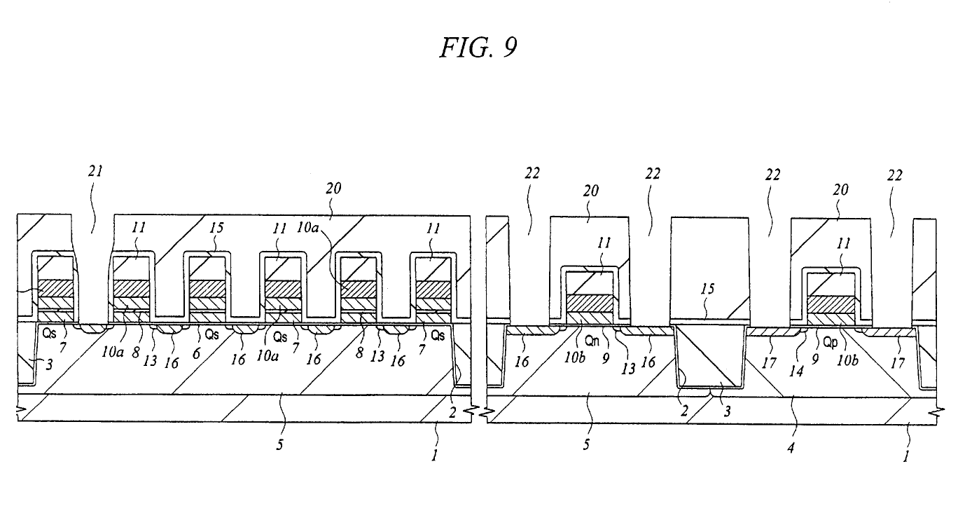

Next, as shown in FIG. 9, the BPSG film 20 and the silicon nitride film 15 are dry-etched with using a photoresist film (not shown) as a mask, thereby forming contact holes 21 and 22 on the source and drain (n⁺-type semiconductor region 16 and p⁺-type semiconductor region 17) of the MISFET. Note that, in this embodiment, the micro-scratches S are eliminated by performing the reflow after the BPSG film 20 is polished for its surface planarization. Therefore, it is unnecessary to form the insulating film to fill the micro-scratches on the BPSG film 20 in advance of the processes for forming the contact holes 21 and 22.

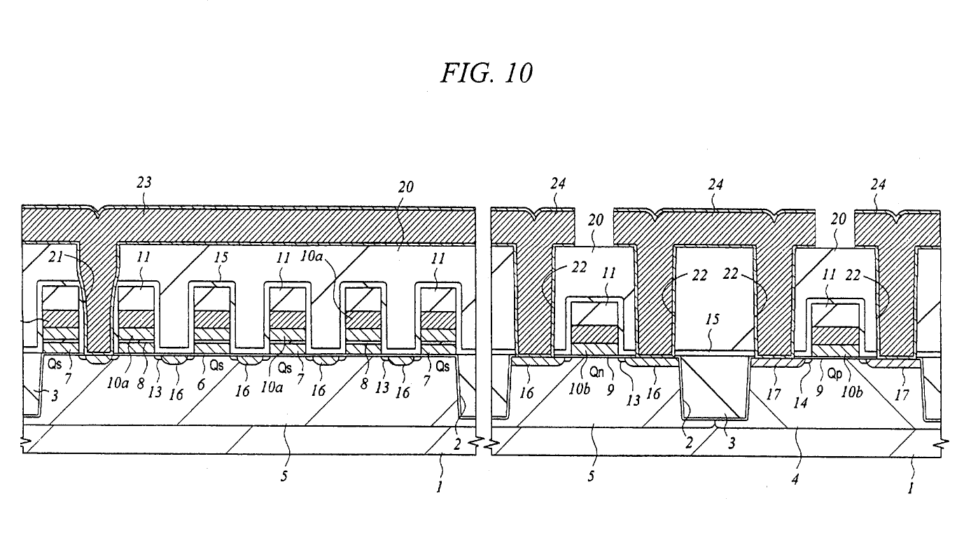

Next, as shown in FIG. 10, Al (aluminum) wirings 23 and 24 electrically connected to the source and drain (n⁺-type semiconductor region 16 and p⁺-type semiconductor region 17) of the MISFET are formed over the BPSG film 20. The Al wirings 23 and 24 are formed in the following manner. That is, a TiN film, an Al alloy film, and a TiN film are sequentially deposited over the BPSG film 20 and in the contact holes 23 and 24. Thereafter, these films are patterned by the dry-etching using a photoresist film as a mask.

Thereafter, though not shown, about two layers of Al wirings are formed on the Al wirings 23 and 24 with interposing an interlayer dielectric therebetween. In this manner, the memory-logic embedded LSI is completed.

As described above, according to the manufacturing method of the present invention, it is possible to surely planarize the BPSG film 20 with the optimal polishing amount and also to reduce the micro-scratches. Therefore, the reliability and the manufacturing yield of the memory-logic embedded LSI can be improved.

Also, since the micro-scratches caused when the BPSG film 20 is polished are filled by the use of the reflow, the process for forming an insulating film to be used to fill the micro-scratches on the BPSG film 20 becomes unnecessary, and thus, the simplification of the process for manufacturing a memory-logic embedded LSI is achieved.

In the foregoing, the invention made by the inventors of the present invention has been concretely described based on the embodiment. However, it is needless to say that the present invention is not limited to the foregoing embodiment and various modifications and alterations can be made within the scope of the present invention.

In the foregoing embodiment, the case where a BPSG film is used between a MISFET and an Al wiring formed over the MISFET has been described. However, the present invention is not limited to this, and it is possible to apply the present invention to the case where a BPSG film is used as a part of an interlayer dielectric that insulates the Al wirings with each other provided on and below the insulating film.

Also, in the foregoing embodiment, the case where the present invention is applied to the LSI in which both the flash memory and the logic LSI are provided has been described. However, the present invention is not limited to this, and it is possible to widely apply the present invention to the device in which a BPSG film is used as a material of an insulating film.

The advantages achieved by the typical ones of the inventions disclosed in this application will be briefly described as follows.

The surface of a BPSG film is polished by the CMP method under the condition that the amount of polishing is within a range of 90 nm and 300 nm, and then, the reflow process of the BPSG film is performed. In this manner, it is possible to achieve the planarization of the BPSG film and the reduction of the micro-scratches.

What is claimed is:

1. A method of manufacturing a semiconductor integrated circuit device, comprising the steps of:
(a) forming a first insulating film mainly made of BPSG over a main surface of a semiconductor substrate;
(b) performing a polishing process of the surface of the first insulating film by the use of the CMP method under the condition that the amount of polishing is within a range of 90 to 300 nm; and
(c) after the step (b), performing a thermal treatment to the semiconductor substrate to reflow the first insulating film.

2. The method of manufacturing a semiconductor integrated circuit device according to claim 1,
wherein the amount of the polishing of the first insulating film by the CMP method is within a range of 100 to 250 nm.

3. The method of manufacturing a semiconductor integrated circuit device according to claim 2,
wherein the amount of the polishing of the first insulating film by the CMP method is within a range of 120 to 200 nm.

4. The method of manufacturing a semiconductor integrated circuit device according to claim 1,
wherein the thermal treatment to the semiconductor substrate is performed in an nitrogen gas atmosphere to which oxygen gas is added.

5. The method of manufacturing a semiconductor integrated circuit device according to claim 1, further comprising the steps of: after the step (c), forming a first conductive film onto the first insulating film without forming any insulating film therebetween; and forming a first wiring by patterning the first conductive film.

6. The method of manufacturing a semiconductor integrated circuit device according to claim 1, further comprising the step of: before the step (a), forming a plurality of MISFETs each having a floating gate and a control gate over the main surface of the semiconductor substrate.

7. A method of manufacturing a semiconductor integrated circuit device, comprising the steps of:
(a) forming a plurality of MISFETs over a main surface of a semiconductor substrate;
(b) after the step (a), forming a first insulating film mainly made of BPSG over the main surface of the semiconductor substrate;
(c) performing a polishing process to the surface of the first insulating film by the use of the CMP method under the condition that the amount of polishing is within a range of 90 nm to 300 nm; and
(d) after the step (c), performing a thermal treatment to the semiconductor substrate to reflow the first insulating film.

8. The method of manufacturing a semiconductor integrated circuit device according to claim 7,
wherein the amount of the polishing of the first insulating film by the CMP method is within a range of 100 to 250 nm.

9. The method of manufacturing a semiconductor integrated circuit device according to claim 8,
wherein the amount of the polishing of the first insulating film by the CMP method is within a range of 120 to 200 nm.

10. The method of manufacturing a semiconductor integrated circuit device according to claim 7,
wherein the thermal treatment of the semiconductor substrate is performed in an nitrogen gas atmosphere to which oxygen gas is added.

11. The method of manufacturing a semiconductor integrated circuit device according to claim 7,
wherein the plurality of MISFETs include MISFETs for a logic circuit and MISFETs for a non-volatile memory having a floating gate and a control gate.

12. The method of manufacturing a semiconductor integrated circuit device according to claim 7, after the step (d), further comprising the steps of:
(e) forming a plurality of contact holes which reach the surface of the semiconductor substrate by etching some parts of the first insulating film;
(f) forming a first conductive film on the first insulating film and in the contact holes without forming any insulating film therebetween; and
(g) patterning the first conductive film to form a first wiring over the first insulating film.

13. The method of manufacturing a semiconductor integrated circuit device according to claim 12,
wherein the first conductive film is mainly made of aluminum.

14. The method of manufacturing a semiconductor integrated circuit device according to claim 13, further comprising the step of:
forming two or more layers of wirings formed of conductive films mainly made of aluminum over the first wiring.

15. The method of manufacturing a semiconductor integrated circuit device according to claim 7,
wherein the first insulating film is deposited by the CVD method using source gas containing ozone and tetraethoxy silane as main components, and the first insulating film contains phosphorus of 6 molar concentration and boron of 13 molar concentration.

16. The method of manufacturing a semiconductor integrated circuit device according to claim 7,
wherein the step (b) includes the step of reforming the first insulating film by performing a thermal treatment at about 850° C. to the semiconductor substrate after the formation of the first insulating film, and the thermal treatment in the step (d) is performed at about 900° C.
